(19) United States
(12) Patent Application Publication
(10) Pub. No.: US 2025/0175588 A1
(43) Pub. Date: May 29, 2025

(54) HEAD-MOUNTED DISPLAY APPARATUS

(71) Applicant: Coretronic Corporation, Hsin-Chu (TW)

(72) Inventors: Wei-Min Chien, Hsin-Chu (TW); Tung-Chou Hu, Hsin-Chu (TW)

(73) Assignee: Coretronic Corporation, Hsin-Chu (TW)

(21) Appl. No.: 18/950,150

(22) Filed: Nov. 17, 2024

(30) Foreign Application Priority Data
Nov. 23, 2023 (CN) 202311580806.8

(51) Int. Cl. H04N 13/398; H04N 13/344; H05K 7/20

(52) U.S. Cl. CPC H04N 13/398; H04N 13/344; H05K 7/20963

(57) ABSTRACT

A head-mounted display apparatus including a casing, an optical engine module, an imaging module, a heat sink, a denoiser, a sensing module, and a control module. The casing includes a body part, from which extends a supporting part. The optical engine and imaging modules are disposed in the body part. An image projected by the optical engine module is displayed on the imaging module. The heat sink is disposed alongside the optical engine module. The sensing module is disposed in the supporting part to detect audio or/and vibration signals generated by the heat sink. The control module is electrically connected to the heat sink, denoiser and sensing module. The control module receives the audio or/and vibration signals detected by the sensing module and controls the denoiser to generate a reverse shock wave to eliminate the audio or/and vibration signals generated by the heat sink.

### CROSS-REFERENCE TO RELATED APPLICATION

This application claims the priority benefit of China application serial no. 202311580806.8, filed on Nov. 23, 2023. The entirety of the above-mentioned patent application is hereby incorporated by reference herein and made a part of this specification.

### BACKGROUND

### Technical Field

The disclosure relates to a display apparatus, and in particular to a head-mounted display apparatus.

### Description of Related Art

Since a head-mounted display apparatus is worn on a user's head, wearing comfort and weight are crucial factors to be considered in design. However, if the head-mounted display apparatus has a more powerful function, a chip generates more heat, generally. Correspondingly, a better heat dissipation capability is required. Currently, forcing convection by using a fan or other methods is a better solution for heat dissipation. However, a fan also brings vibration and noise problems. How to improve comfort for the user under the premise of high heat dissipation efficiency has been the current research direction.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

The head-mounted display apparatus of the disclosure includes a casing, an optical engine module, an imaging module, a heat sink, a denoiser, a sensing module, and a control module. The casing includes a body part and a supporting part extending from the body part. The optical engine module is disposed in the body part. The imaging module is disposed in the body part and alongside the optical engine module. An image projected by the optical engine module is displayed on the imaging module. The heat sink is disposed alongside the optical engine module. The denoiser is disposed in the supporting part. The sensing module is disposed in the supporting part and adapted to detect an audio signal or/and a vibration signal generated by the heat sink. The control module is electrically connected to the heat sink, the denoiser and the sensing module. The control module receives the audio signal or/and the vibration signal detected by the sensing module and controls the denoiser to generate a reverse shock wave to eliminate the audio signal or/and the vibration signal generated by the heat sink.

Other objectives, features and advantages of the present disclosure will be further understood from the further technological features disclosed by the embodiments of the present disclosure wherein there are shown and described preferred embodiments of this disclosure, simply by way of illustration of modes best suited to carry out the disclosure.

### BRIEF DESCRIPTION OF THE DRAWINGS

FIG. 1 is a diagram illustrating a three-dimensional perspective view of a head-mounted display apparatus according to an embodiment of the disclosure.

FIG. 2 is a diagram illustrating a top perspective view of the head-mounted display apparatus in FIG. 1.

FIG. 3 is a schematic diagram illustrating a sensing module and a heat sink in FIG. 1.

FIG. 4 is a diagram illustrating the top perspective view of the head-mounted display apparatus according to an embodiment of the disclosure.

FIG. 5 is a diagram illustrating the three-dimensional perspective view of the head-mounted display apparatus according to an embodiment of the disclosure.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

The disclosure provides a head-mounted display apparatus having a good heat dissipation and a good wearing comfort.

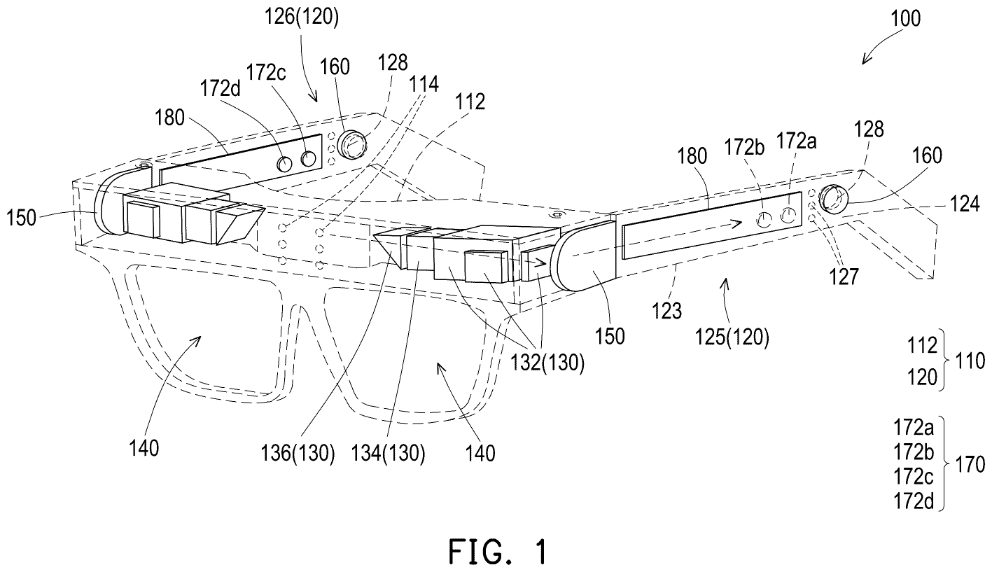

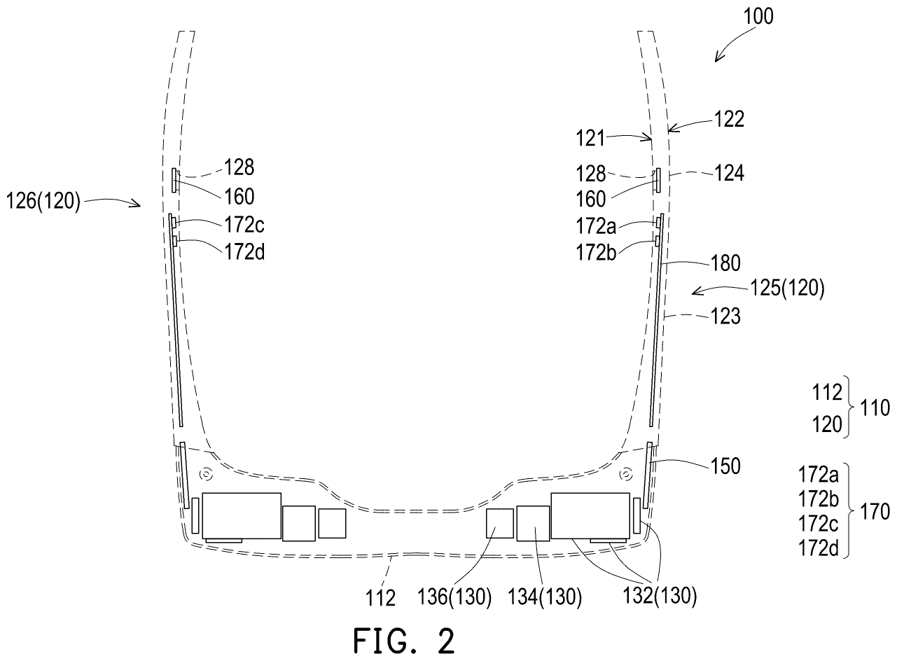

FIG. 1 is a diagram illustrating a three-dimensional perspective view of a head-mounted display apparatus according to an embodiment of the disclosure. FIG. 2 is a diagram illustrating a top perspective view of the head-mounted display apparatus in FIG. 1.

Referring to FIGS. 1 and 2, a head-mounted display apparatus 100 in this embodiment is, for example, VR glasses or AR glasses. A type of the head-mounted display apparatus 100 is not limited thereto. The head-mounted display apparatus 100 in this embodiment includes a casing 110, an optical engine module 130, an imaging module 140, a heat sink 150, a denoiser 160, a sensing module 170, and a control module 180.

The casing 110 includes a body part 112 and a supporting part 120 extending from the body part 112. In this embodiment, two rims of the glasses are used as an example of the body part 112, which is worn in front of a human face. Temples contacting ears of a user is used as an example of the supporting part 120. The supporting part 120 includes a first supporting part 125 and a second supporting part 126, which are two temples.

Each of the first supporting part 125 and the second supporting part 126 includes a connection part 123 and a bracket part 124. The connection part 123 is connected between the body part 112 and the bracket part 124. An inner surface 121 of the bracket part 124 is adapted to contact a skin. The bracket part 124 is located at an end of the corresponding first supporting part 125 or the second supporting part 126, and the bracket part 124 is shorter than a half of the first supporting part 125 or the second supporting part 126 in length.

In this embodiment, there are two optical engine modules 130 and two imaging modules 140 in quantity. The two optical engine modules 130 are disposed in the body part 112. The two imaging modules 140 are disposed in the body part 112 and below the two optical engine modules 130 respectively. Images projected by the two optical engine modules 130 are displayed on the two imaging modules 140 respectively. In this embodiment, the imaging modules 140 are, for example, lenses. A quantity of the imaging module 140 may be determined according to a quantity of the lens of the head-mounted display device 100, but the disclosure is not limited thereto. In other embodiments, there is one lens of the head-mounted display apparatus 100 in quantity. In addition, a single lens having two imaging areas may be defined as two imaging modules.

In this embodiment, each optical engine module 130 includes an image source module 132, a lens element 134, and a light guiding element 136. The image source module 132 includes, for example, a light emitting element, a light valve, and a light splitting and combining element. The light emitted from the image source module 132 forms an image light, which facilitates imaging on the imaging module 140 by passing through the lens element 134 and the light guiding element 136. Of course, in other embodiments, a quantity and a position of the optical engine module 130 and the imaging module 140 are not limited thereto.

In this embodiment, there are two heat sinks 150 in quantity. The two heat sinks 150 are disposed alongside the two optical engine modules 130 respectively. In this embodiment, each of the heat sinks 150 is, for example, a piezoelectric fan. The piezoelectric fan has a piezoelectric film and a metal plate. A metal has a good thermal conductivity. Thus, a heat dissipation is achieved by distributing heat evenly on the metal plate and vibrating the piezoelectric film to generate an airflow to cool the metal plate. In other embodiments, the heat sink 150 may also be a blowing fan or an axial fan. A type of the heat sink 150 is not limited thereto.

As seen in FIG. 1, the body part 112 has an air inlet 114, and the supporting part 120 has an air outlet 127. The air outlet 127 is, for example, disposed in the bracket part 124. The air inlet 114 is connected to the air outlet 127. The heat sink 150 is located between the optical engine module 130 and the control module 180. Each dashed arrow in FIG. 1 represent a direction of an airflow. When the heat sink 150 is in operation, an airflow is introduced from the air inlet 114 and flows through the optical engine module 130, the heat sink 150, and the control module 180 in sequence, and then exits from the air outlet 127 to dissipate heat for the optical engine module 130 and the control module 180. It is noted that the airflow in FIG. 1 is only schematically shown in the right half. The airflow in the left half is hidden.

In addition, there are two denoisers 160 in quantity. The two denoisers 160 are disposed in the first supporting part 125 and the second supporting part 126 respectively. Each of the denoisers 160 is disposed in the bracket part 124 of the corresponding first supporting part 125 or the second supporting part 126. The denoisers 160 are microspeakers (e.g., in-ear earphones) or conduction speakers (e.g., bone conduction earphones). The denoisers 160 are mainly used to eliminate a sound generated by the heat sinks 150. In an embodiment, the denoiser 160 may also eliminate the sound and a vibration generated by the heat sink 150 at the same time.

As shown in FIG. 2, in this embodiment, the denoiser 160 is exposed to a hole 128 on the inner surface 121 of the supporting part 120 and spaced apart from the outer surface 122 of the supporting part 120. The inner surface 121 is a contact surface that contacts a skin of a user, and the outer surface 122 is an appearance surface that is shown on the outside. In other embodiments, the denoiser 160 may also be fixed to the inner surface 121 of the supporting part 120 and spaced apart from the outer surface 122 of the supporting part 120.

Since the denoiser 160 is exposed to the inner surface 121 of the supporting part 120, a vibration generated by the denoiser 160 is transmitted to a temporal bone of the user, then to a cochlea, and finally to an auditory nerve through the hole 128 of the casing 110 to allow the user to hear the sound. In an embodiment, if the denoiser 160 is connected to the inner surface 121, the vibration generated by the denoiser 160 is transmitted to the user through the supporting part 120 of the casing 110 to allow the user to hear the sound.

The sensing module 170 is disposed in the supporting part 120 to detect an audio signal or/and a vibration signal generated by the heat sink 150. The sensing module 170 includes at least four sensors 172a to 172d. The sensors 172a to 172d are, for example, microphones or/and MEMS vibration sensors.

The control module 180 is disposed in the supporting part 120 and electrically connected to the heat sink 150, the denoiser 160 and the sensing module 170. In this embodiment, there are two control modules 180 in quantity. The two control modules 180 are disposed in the first supporting part 125 and the second supporting part 126 respectively, but in other embodiments, the control may be performed by a single control module 180.

It is noted that a sound wave and a vibration wave are essentially the same. The vibration wave relates to a vibration of an object and the sound wave relates to a vibration of air, making a source of the sound wave is the vibration wave. Thus, the sensors 172a to 172d sense the vibration of the object or the air, and the position of a sound source or/and a vibration source may be deduced by a joint sensing of the sensors 172a to 172d.

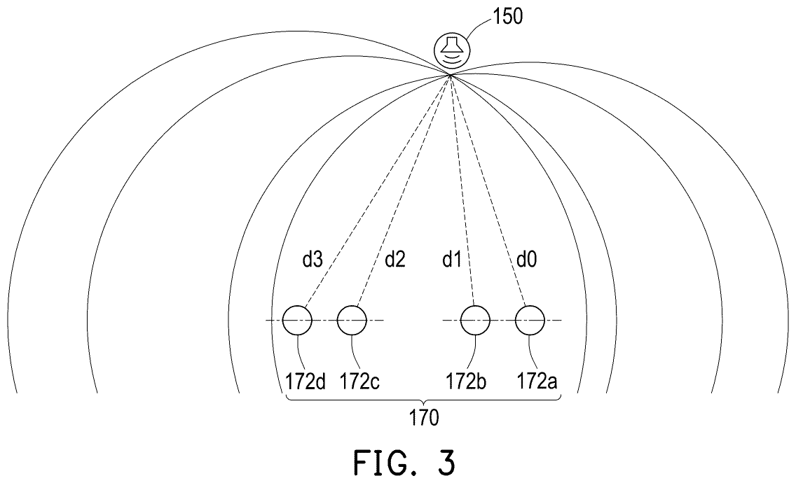

FIG. 3 is a schematic diagram illustrating a sensing module and a heat sink in FIG. 1. It is noted that FIG. 3 is simply a schematic representation and does not illustrate an actual position of each of the sensors 172a to 172d in relation to the heat sink 150. Referring to FIGS. 2 and 3, in this embodiment, a quantity of four sensors 172a to 172d are used for example, but the quantity of the sensors is not limited thereto. The four sensors 172a to 172d are disposed in the first supporting part 125 and the second supporting part 126 respectively, and the four sensors 172a to 172d are at different distances d0 to d3 from the heat sink 150.

As shown in FIG. 3, due to the different distances (d0 to d3) of the four sensors 172a to 172d from the heat sink 150 (the sound source), there are time differences between the sound waves detected by the four sensors. The control module 180 calculates to obtain the distances do to d3 by a corresponding time difference between the two sensors 172a and 172b in the first supporting part 125 and a corresponding time difference between the two sensors 172c and 172d in the second supporting part 126. Then, the control module 180 makes a circle centered on each of the sensors 172a to 172d, and uses the distance deduced from the time difference as a radius. The intersection of the four circles is a position of the heat sink 150 (the sound source) relative to the sensors 172a to 172d.

Since the sensing module 170 is not located where a human ear receives the sound, to effectively eliminate the noise transmitted from the heat sink 150 to the human ear, a signal transmitted to the human ear must be deduced from the signal detected by the sensing module 170. Since the positions of the sensors 172a to 172d relative to the human ear are known, the control module 180 may deduce a magnitude of the sound wave received by the human ear based on the obtained position of the heat sink 150 (the sound source), a magnitude of the sound wave of the heat sink 150, and the positions of the sensors 172a to 172d relative to the human ear.

Thus, the control module 180 of the head-mounted display apparatus 100 determines a direction, a distance, an audio amplitude and an audio frequency of the heat sink 150 relative to the sensing module 170 according to the audio signal or/and the vibration signal received by the at least four sensors 172a to 172d of the sensing module 170. This information is processed by the control module 180 to control the denoiser 160 to generate reverse shock waves (shock waves having the same amplitude but in an opposite phase) in the right sequence to accurately eliminate the noise or/and the vibration generated by the heat sink 150. Thus, the heat sink 150 of the head-mounted display apparatus 100 may operate at a high power level, which significantly improves a heat dissipation capacity.

It is noted that a sound and a vibration have different frequencies. The vibration usually has a low frequency, and the sound usually has a medium frequency. If the denoiser 160 is to eliminate both the sound and the vibration, the denoiser 160 needs to generate reverse shock waves with different frequencies. Of course, as long as the denoiser 160 eliminates the noise generated by the heat sink 150, the user's requirement for comfort may be satisfied.

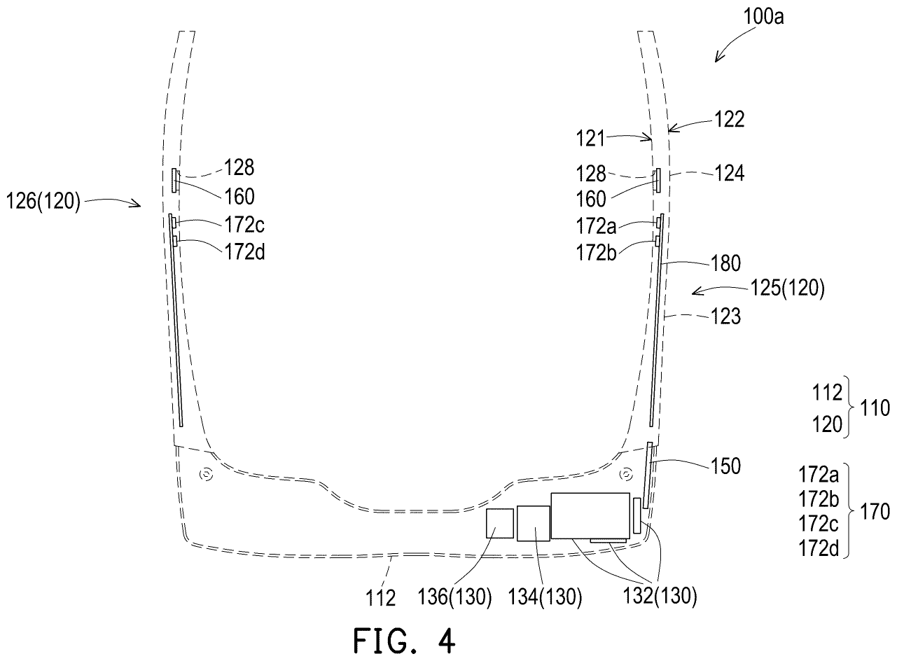

FIG. 4 is a diagram illustrating the top perspective view of the head-mounted display apparatus according to an embodiment of the disclosure. Referring to FIG. 4, a difference between this embodiment and the embodiment of FIG. 2 is that, in this embodiment, there is one optical engine module 130 and one heat sink 150 in quantity. Specifically, the optical engine module 130 and the heat sink 150 of the disclosure are disposed on a left side of a head-mounted display apparatus 100a. In order to maintain the effectiveness of eliminating the noise generated by the heat sink 150 for both ears and the accuracy of measuring the noise, the denoiser 160 and the sensing module 170 may be disposed in the supporting part 120 (i.e. both of the first supporting part 125 and the second supporting part 126). In other embodiments, the noise reducer 160 and the sensing module 170 may be optionally disposed only in the supporting part 120 on a side (i.e. only one of the first supporting part 125 and the second supporting part 126) where the optical engine module 130 is disposed.

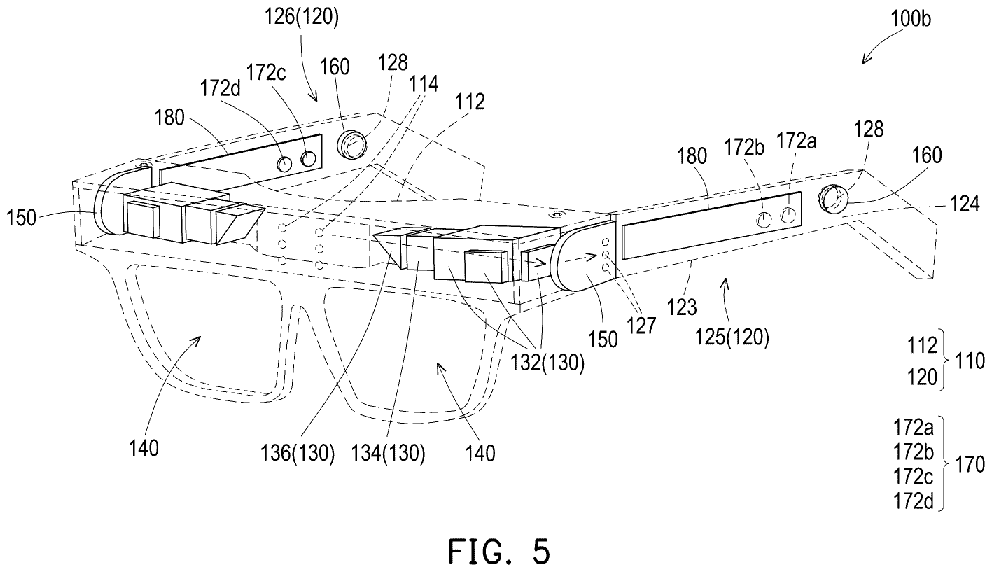

FIG. 5 is a diagram illustrating the three-dimensional perspective view of the head-mounted display apparatus according to an embodiment of the disclosure. Referring to FIG. 5, a difference between this embodiment and the embodiment of FIG. 1 is a position where the air outlet 127 is disposed. Specifically, in this embodiment, the air outlet 127 may be disposed in the body part 112 of a head-mounted display apparatus 100b. For example, the air inlet 114 is disposed in a middle area of the body part 112 (e.g., between the two imaging modules 140), and the air outlet 127 is disposed in areas on both sides of the body part 112 (e.g., near the area of the supporting part 120). In particular, the air outlet 127 in FIG. 5 is only schematically shown in the right half, and the position where the air outlet 127 is disposed is not limited to the position shown in FIG. 5. It can be understood that disposing the air outlet 127 at a downstream of the airflow generated by the heat sink 150 is sufficient.

In summary, the optical engine module and the imaging module of the head-mounted display apparatus of the disclosure are disposed in the body part of the casing, and the heat sink is disposed alongside the optical engine module to dissipate heat from the optical engine module. The denoiser and the sensing module are disposed in the supporting part of the casing. The sensing module is adapted to detect the audio signal or/and the vibration signal generated by the heat sink. The control module receives the audio signal or/and the vibration signal detected by the sensing module and controls the denoiser to generate a reverse shock wave to eliminate the audio signal or/and the vibration signal generated by the heat sink. As a result, a noise or a vibration experienced by a user is significantly reduced while the head-mounted display apparatus still provides a good heat dissipation effect.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A head-mounted display apparatus, comprising:
a casing with a body part and a supporting part extending from the body part;
an optical engine module disposed in the body part;
an imaging module disposed in the body part and located alongside the optical engine module, wherein an image projected by the optical engine module is displayed on the imaging module;
a heat sink disposed alongside the optical engine module;
a denoiser disposed in the supporting part;
a sensing module disposed in the supporting part and adapted to detect an audio signal or/and a vibration signal generated by the heat sink; and
a control module electrically connected to the heat sink, the denoiser and the sensing module,
wherein the control module receives the audio signal or/and the vibration signal detected by the sensing module and controls the denoiser to generate a reverse shock wave to eliminate the audio signal or/and the vibration signal generated by the heat sink.

2. The head-mounted display apparatus of claim 1, wherein the sensing module comprises at least four sensors, each of the at least four sensors being at a different distance from the heat sink, wherein the control module determines a direction, a distance, an audio amplitude and an audio frequency of the heat sink relative to the sensing module according to the audio signal or/and the vibration signal received by the at least four sensors.

3. The head-mounted display apparatus of claim 2, wherein the supporting part comprises a first supporting part and a second supporting part, and the at least four sensors are disposed in the first supporting part and the second supporting part respectively.

4. The head-mounted display apparatus of claim 1, wherein the control module is disposed in the supporting part, wherein the body part has an air inlet and the supporting part has an air outlet, the air inlet being connected to the air outlet, wherein the heat sink is located between the optical engine module and the control module.

5. The head-mounted display apparatus of claim 4, wherein the supporting part comprises a connection part and a bracket part, the connection part being connected to the body part, wherein the air outlet and the denoiser are disposed in the bracket part.

6. The head-mounted display apparatus of claim 1, wherein the heat sink is a piezoelectric fan.

7. The head-mounted display apparatus of claim 1, wherein the denoiser is a microspeaker or a conduction speaker.

8. The head-mounted display apparatus of claim 1, wherein the denoiser is fixed to an inner surface of the supporting part corresponding to the denoiser and spaced apart from an outer surface of the supporting part, or the denoiser is exposed to the inner surface of the supporting part corresponding to the denoiser and spaced apart from the outer surface of the supporting part.

9. The head-mounted display apparatus of claim 1, wherein a quantity of the optical engine module is two and a quantity of the heat sink is two, the two heat sinks being disposed alongside the two optical engine modules respectively, wherein a quantity of the denoiser is two and the supporting part comprises a first supporting part and a second supporting part, the two denoisers being disposed in the first supporting part and the second supporting part respectively.

10. The head-mounted display apparatus of claim 1, wherein the optical engine module comprises a light emitting element, a lens unit, and a light guiding element, wherein the image is formed by imaging by a light emitted from the light emitting element and passing through the lens unit, the image being converged on the imaging module through the light guiding element.
